(19) United States
(12) Patent Application Publication
(10) Pub. No.: US 2007/0033457 A1
(43) Pub. Date: Feb. 8, 2007

(54) CIRCUIT BOARD AND METHOD FOR MANUFACTURING THE SAME

(75) Inventors: Sung-Joo PARK, Gyeonggi-do, (KR); Jae-Jun LEE, Gyeonggi-do (KR); Byung-Se SO, Gyeonggi-do (KR); Jung-Joon LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do (KR)

(21) Appl. No.: 11/459,887

(22) Filed: Jul. 25, 2006

(30) Foreign Application Priority Data
Jul. 25, 2005 (KR) 2005-0067448

(51) Int. Cl. G01R 31/28

(52) U.S. Cl. 714/724

(57) ABSTRACT

A circuit board and a method of manufacturing the same are disclosed. Embodiments of the circuit board may include a dielectric substrate, a first via structure comprising a first via-hole, which is defined through the dielectric substrate, and a plurality of first vias that are formed on an inner wall of the first via-hole and to connect a plurality of signal patterns positioned on the upper and lower surfaces of the dielectric substrate.

This application claims priority from Korean Patent Application No. 10-2005-0067448 filed on Jul. 25, 2005, in the Korean Intellectual Property Office, the disclosure of which is incorporated by reference.

### BACKGROUND

1. Field of the Invention

The present invention relates, in general, to a circuit board and a method for manufacturing the same, and more particularly to a circuit board which has improved operational characteristics, and a method for manufacturing the same.

2. Description of the Prior Art

As semiconductor devices become highly integrated, miniaturized, and high-speed, the functionality of the circuit boards used in these devices becomes more important. Specifically, it is important to design a circuit board capable of preventing signal distortion. In a circuit board, complicated signal patterns can be stably formed in a multi-layered structure in such a way as to be stacked over one another, and signal patterns formed in different layers are electrically connected with each other by way of a via. However, because it is difficult to control the characteristic impedance of the via, signal distortion may occur.

For example, in the case of a single-ended signal pattern, since the distance between a via and a reference layer is not constant, the capacitance or inductance of the via varies.

Also, differential signal patterns, which comprise a pair of signal patterns positioned adjacent to each other, are used to transmit a signal, along with a complementary signal. In this case, because common mode noise generated by environmental circumstances is offset, it is possible to improve signal integrity. In particular, it is important that the pair of signal patterns be held at a constant distance from each other. If the distance between the pair of signal patterns varies, an impedance mismatch may occur and, as a result, the signal may be reflected causing signal distortion.

FIG. 1 is a plan view illustrating a conventional circuit board, and FIG. 2 is a cross-sectional view taken along the line II-II′ of FIG. 1.

Referring to FIGS. 1 and 2, the conventional circuit board 1 comprises a dielectric substrate 10, signal patterns 20, 25, 40, and 45, and via structures 30 and 35. The via structures 30 and 35 include via-holes 31 and 36 and vias 32 and 37. The vias 32 and 37 are respectively composed of connection parts 32a, 37a and 32b, 37b. The pair of upper signal patterns 20 and 25 are respectively connected with the pair of lower signal patterns 30 and 35 by way of the pair of vias 32 and 37. It should be noted that the spacing “a” between the pair of vias 32 and 37 is greater than the distance “b” between the pair of upper signal patterns 20 and 25. As a consequence, since connection regions 29, where the pair of upper signal patterns 20 and 25 and the pair of vias 32 and 37 are connected with each other, diverge, the pair of upper signal patterns 20 and 25 cannot be held at a constant distance from each other, and signal distortion is likely to occur.

### SUMMARY

Accordingly, embodiments of the present invention provide a circuit board which has improved operational characteristics, and a method for manufacturing a circuit board having the improved operational characteristics.

An exemplary embodiment of the present invention is directed to a circuit board including a dielectric substrate, and a first via structure including a first via-hole which is defined through the dielectric substrate and a plurality of first vias which are formed on an inner wall of the first via-hole and connect a plurality of patterns positioned on upper and lower surfaces of the dielectric substrate.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a plan view illustrating a conventional circuit board;

FIG. 2 is a cross-sectional view taken along the line II-II′ of FIG. 1;

FIGS. 3 and 4 are a perspective view and a plan view, respectively, illustrating a via structure adopted in a circuit board in accordance with an embodiment of the present invention;

FIG. 5 is a cross-sectional view taken along the line V-V′ of FIG. 4;

FIGS. 6 through 8 are plan views explaining via structures used in the circuit board in accordance with an embodiment of the present invention;

FIG. 9 is a conceptual view explaining characteristics of the circuit board in accordance with an embodiment of the present invention;

FIG. 10 shows plan views explaining via structures adopted in a circuit board in accordance with another embodiment of the present invention;

FIG. 11 is a cross-sectional view illustrating a circuit board in accordance with another embodiment of the present invention;

FIG. 12 is a flowchart illustrating a method for manufacturing a circuit board in accordance with another embodiment of the present invention;

FIGS. 13A through 13D are plan views explaining a method for manufacturing a circuit board in accordance with the another embodiment of the present invention; and

FIG. 14 is a flowchart illustrating a method for manufacturing a circuit board in accordance with still another embodiment of the present invention.

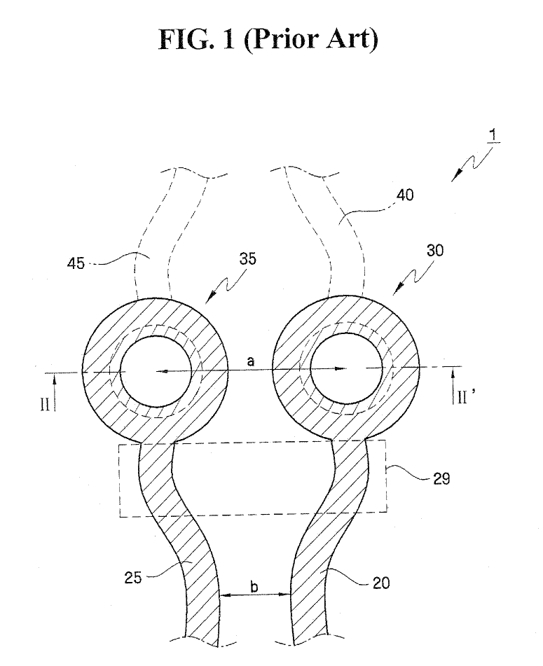

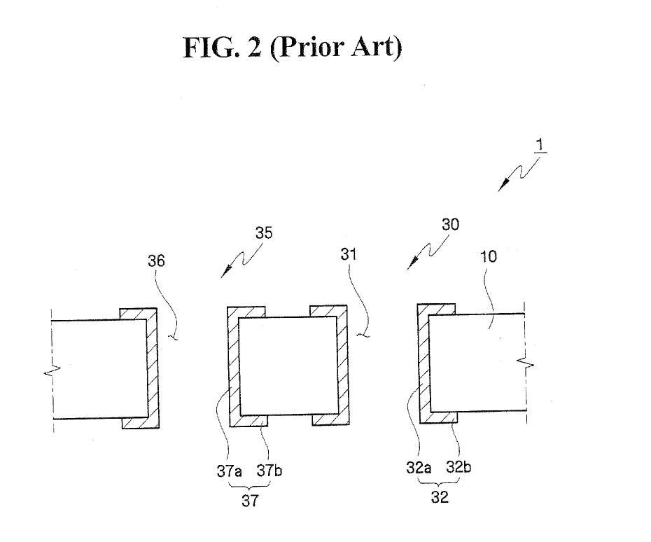

### DETAILED DESCRIPTION

Reference will now be made in greater detail to exemplary embodiments of the invention, which are illustrated in the accompanying drawings. Wherever possible, the same reference numerals will be used throughout the drawings and the description to refer to the same or like parts.

A circuit board according to the present invention may include a PCB (printed circuit board), an FPCB (flexible PCB), an FRPCB (flexible rigid PCB), or a ceramic substrate, but is not limited to such examples. For the sake of explanatory convenience, a PCB will be exemplified in the following detailed description.

The circuit board of the present invention may be adapted to a package board, a multi-chip module board, or a general-type motherboard, but again is not limited to such examples.

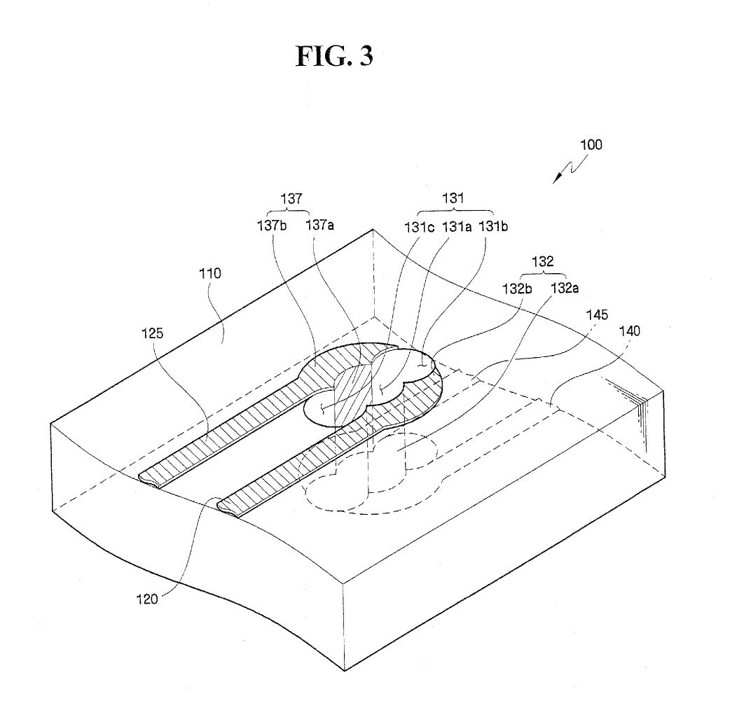

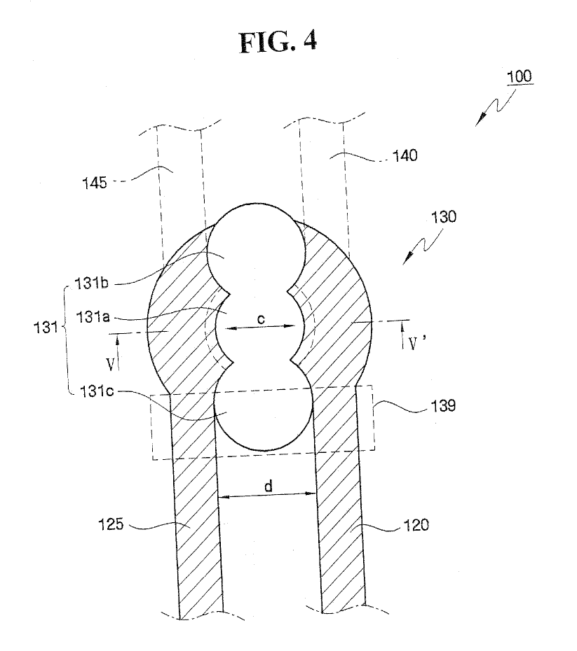

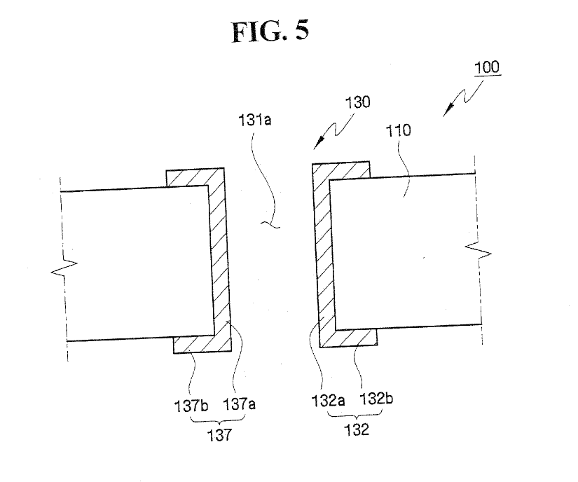

FIGS. 3 and 4 are respectively a perspective view and a plan view illustrating a via structure adopted in a circuit board in accordance with an embodiment of the present invention, and FIG. 5 is a cross-sectional view taken along the line V-V′ of FIG. 4. While a dielectric substrate having a single-layered structure is illustrated in one embodiment of the present invention for the sake of explanatory convenience, it should be understood that the present invention is not limited to this example.

Referring to FIGS. 3 through 5, a circuit board 100 in accordance with an embodiment of the present invention comprises a dielectric substrate 110, signal patterns 120, 125, 140, and 145, and a via structure 130.

A plurality of semiconductor devices are mounted to the dielectric substrate 110. The signal patterns 120, 125, 140, and 145, which electrically connect the semiconductor devices, are formed on both surfaces of the dielectric substrate 110. In order to be appropriate for use in the circuit board 100, the dielectric substrate 110 must have excellent dimensional stability, heat resistance, chemical resistance, and flame retardancy. Further, in order to allow the vias 132 and 137 to be formed thereon, the dielectric substrate 110 must have excellent platability. Therefore, for example, the circuit board 100 may include FRP (fiberglass reinforced plastic), BT (bismaleimide triazine), PPE (polyphenylene ether), PPO (polyphenylene oxide) resin, and so forth.

The signal patterns 120, 125, 140, and 145 are formed on both surfaces of the dielectric substrate 110, and function to transmit signals. Each pair of signal patterns 120, 125 and 140, 145 are connected to the via structure 130, and are arranged in one direction. The signal patterns include a pair of upper signal patterns 120 and 125 and a pair of lower signal patterns 140 and 145. The signal patterns 120, 125, 140, and 145 are mainly formed of conductive materials such as, for example, Cu, Al, Ag, Au, Ni, and so on.

When the signal patterns 120, 125, 140, and 145 are used as differential signal patterns, the signal patterns 120 and 140 transmit a signal, and the other signal patterns 125 and 145 transmit a complementary signal, Since the signal and the complementary signal serve as references with respect to each other, even without a separate reference layer, the signal can be transmitted from a source system to a destination system. The differential signal patterns may provide advantages in that common mode noise generated by environmental circumstances may be offset by itself, and high noise immunity can be accomplished. This is because the pair of signal patterns are positioned adjacent to each other and are influenced by the same circumstances.

The via structure 130 includes a via-hole 131, which runs through the dielectric substrate 110, and the pair of vias 132 and 137, which are formed on the inner wall of the via-hole 131, and connect the pair of upper signal patterns 120 and 125 with the pair of lower signal patterns 140 and 145.

The via-hole 131 is defined in a manner such that a plurality of sub via-holes 131a, 131b and 131c overlap one another. Specifically, sub via-holes 131b and 131c (which are also referred to as offset sub via-holes 131b and 131c) can be positioned adjacent to the central sub via-hole 131a and spaced a predetermined distance away from the central via-hole 131a. For example, as shown in FIG. 3, the via-hole 131 includes the central sub via-hole 131a and two sub via-holes 131b and 131c, which are positioned above and below (in the same plane) the central sub via-hole 131a. While the plurality of sub via-holes 131a, 131b, and 131c may have the same shape, the present invention is not limited to such a shape. For example, the size of the central sub via-hole 131a may be greater than that of the sub via-holes 131b and 131c.

The vias 132 and 137 are divided into connection parts 132a and 137a, and pad parts 132b and 137b. The connection parts 132a and 137a are formed on the inner wall of the central sub via-hole 131a, and the pad parts 132b and 137b are formed on the upper and lower surfaces of the dielectric substrate 110 adjacent to the central sub via-hole 131a. Due to the fact that the remaining sub via-holes 131b and 131c, which overlap the central sub via-hole 131a, isolate the pair of vias 132 and 137 from each other, the pair of vias 132 and 137 can be formed in one via-hole 131. In this case, the pad parts 132b and 137b of the pair of vias 132 and 137 are formed along the curved edge of the central sub via-hole 131a, which may have a predetermined curvature. The vias 132 and 137 may further be formed to include a conductive material such as, for example, Cu, Al, Ag, Au, Ni, and so on.

Specifically, each pair of signal patterns 120, 125 and 140, 145 may be connected with the vias 132 and 137 and are arranged in one direction. Each pair of signal patterns 120, 125 and 140, 145 have connection regions 139 where they are connected to the vias 132 and 137. According to the present invention, the connection regions 139 are parallel to each other. That is to say, since the pair of vias 132 and 137, which are electrically isolated from each other, are formed in one via-hole 131, even in a state in which the connection regions 139 of the pair of upper signal patterns 120 and 125 do not diverge, the pair of vias 132 and 137 and the pair of upper signal patterns 120 and 125 can be connected with each other. Here, the connection regions indicate the parts where each pair of signal patterns 120, 125 and 140, 145 are connected with the pad parts 132b and 137b of the pair of vias 132 and 137.

The differential impedance of the signal patterns 120, 125, 140, and 145 may be adjusted by the dielectric constant of the dielectric substrate 110 and the configurations of the signal patterns 120, 125, 140, and 145, including, for example, the thickness, width, and interval of the signal patterns 120, 125, 140, and 145. If a signal transmitted through the signal patterns 120, 125, 140, and 145 experiences an impedance change, one portion of the signal may be reflected and the other portion passes through the signal patterns. The reflection of a signal is likely to cause a low gain, noise and a random error that may deteriorate the operational characteristics of the circuit board 100. Hence, as discussed above, it may be important to maintain a constant impedance in the circuit board 100.

In one embodiment of the present invention, when each pair of signal patterns 120, 125 and 140, 145 have the same thickness and width, the differential impedance of the connection regions 139 may be constant since the distance between the connection regions 139 of each pair of signal patterns 120, 125 and 140, 145 is constant. In detail, as set out in equation 1, Z_{diff1}, L₁, and C₁ respectively designate the differential impedance, the self inductance, and the self capacitance of the first upper signal pattern 120. Further, Lₘ₁ and Cₘ₁ respectively designate the mutual inductance and the mutual capacitance between the first upper signal pattern 120 and the second upper signal pattern 125. In particular, Lₘ₁ and Cₘ₁ may be inversely proportional to the distance “d” between the first and second upper signal patterns 120 and 125. In the conventional art, because connection regions must diverge to a certain degree in order to ensure that a pair of upper patterns is connected with a pair of vias, Lₘ₁ and Cₘ₁ decrease and the differential impedance varies. However, as described in the above embodiment of the present invention, because the connection regions 139 of the pair of upper signal patterns 120 and 125 are parallel, it is possible to keep Lₘ₁ and Cₘ₁ constant, and therefore the differential impedance can be kept constant.

$${Z}_{diff 1} = 2 * \sqrt{\frac{{L}_{1} - {L}_{m 1}}{{C}_{1} + {C}_{m 1}}} \qquad ( 1 )$$

Also, in the above embodiment of the present invention, the differential impedance of the pair of vias 132 and 137 can be made to be the same as the differential impedance of each pair of signal patterns 120, 125 and 140, 145, which have a constant value. In detail, as set out in equation 2, Z_{diff2}, L₂, and C₂ respectively designate the differential impedance, the self-inductance, and the self-capacitance of the first via 132, and Lₘ₂ and Cₘ₂ respectively designate the mutual inductance and the mutual capacitance between the first via 132 and the second via 137. In equation 2, L₂ may be proportional to the length of the first via 132, and C₂ may be proportional to the width of the first via 132. Also, as described above, Lₘ₂ and Cₘ₂ may be components which are inversely proportional to the distance “c” (shown in FIG. 4) between the first and second vias 132 and 137. In the above embodiment of the present invention, the differential impedance can additionally be adjusted by regulating the width of and the distance between the pair of vias 132 and 137. In addition, since the vias 132 and 137 are formed on and along the curved surface and edge of the central sub via-hole 131a, which has a predetermined curvature, the distance between the pair of vias 132 and 137 may be defined as the average of the maximum and minimum distances between the pair of vias 132 and 137.

$${Z}_{diff 2} = 2 * \sqrt{\frac{{L}_{2} - {L}_{m 2}}{{C}_{2} + {C}_{m 2}}} \qquad ( 2 )$$

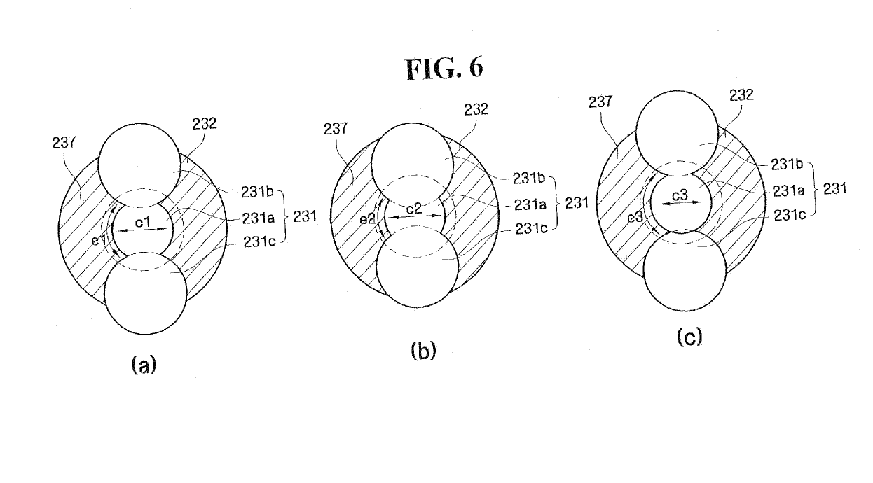

Hereafter, a technique for adjusting the differential impedance will be described with reference to FIGS. 6 through 8.

Referring to FIGS. 6(a) through 6(c), a pair of vias 232 and 237 may be formed using a central sub via-hole 231a and a plurality of sub via-holes 231b and 231c, which have similar shapes and sizes. In this case, depending upon the position where the central sub via-hole 231a and the plurality of sub via-holes 231b and 231c overlap with each other, the widths e1, e2, and e3 of the vias 232 and 237 and the distances c1, c2, and c3 between the pair of vias 232 and 237 may vary.

In detail, when comparing the structure of FIG. 6(b) with the structure of FIG. 6(a), the plurality of sub via-holes 231b and 231c overlap the central sub via-hole 231a to an increased extent. In this case, the width e2 of the respective vias 232 and 237 decreases compared to e1, and the distance c2 between the pair of vias 232 and 237 increases compared to c1. When comparing the structure of FIG. 6(c) with the structure of FIG. 6(a), the plurality of sub via-holes 231b and 231c overlap the central sub via-hole 231a to a decreased extent. In this case, the width e3 of the respective vias 232 and 237 increases compared to e1, and the distance c3 between the pair of vias 232 and 237 decreases compared to c1. Therefore, using this principle, the differential impedance of the vias 232 and 237 can be adjusted.

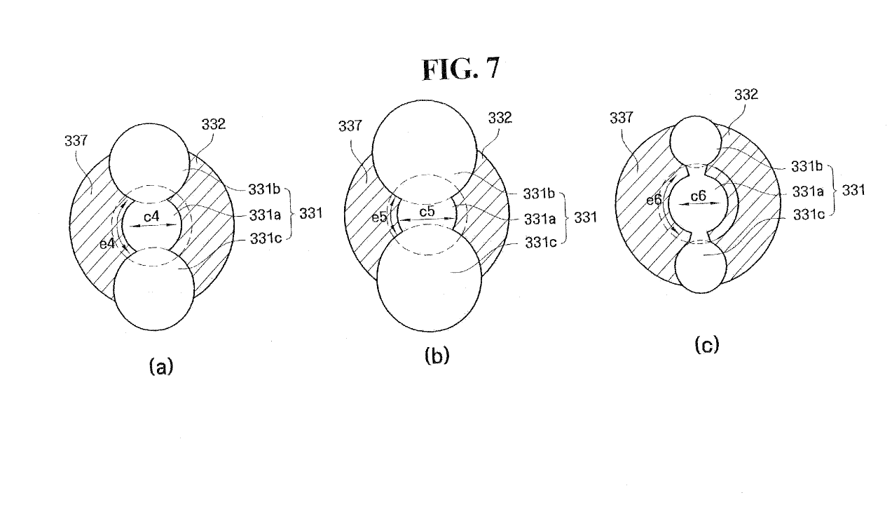

Referring to FIGS. 7(a) through 7(c), a pair of vias 332 and 337 may be formed using a central sub via-hole 331a and a plurality of sub via-holes 331b and 331c which have different sizes. In this case, assuming that the spacing between the central sub via-hole 331a and the plurality of sub via-holes 331b and 331c remains the same, the widths e4, e5, and e6 of the vias 332 and 337 and the distances c4, c5, and c6 between the pair of vias 332 and 337 can vary depending upon the size of the plurality of sub via-holes 331b and 331c.

In detail, comparing the structure of FIG. 7(b) with that of FIG. 7(a), since the sizes of the plurality of sub via-holes 331b and 331c are greater, the plurality of sub via-holes 331b and 331c overlap the central sub via-hole 331a to an increased extent. In this case, the width e5 of the respective vias 332 and 337 decreases compared to e4, and the distance c5 between the pair of vias 332 and 337 increases compared to c4. When comparing the structure of FIG. 7(c) with that of FIG. 7(a), since the size of the plurality of sub via-holes 331b and 331c is decreased, the plurality of sub via-holes 331b and 331c overlap the central sub via-hole 331a to a decreased extent. In this case, the width e6 of the respective vias 332 and 337 increases compared to e4, and the distance c6 between the pair of vias 332 and 337 decreases compared to c4. Therefore, by using this principle, the differential impedance of the vias 332 and 337 can be adjusted.

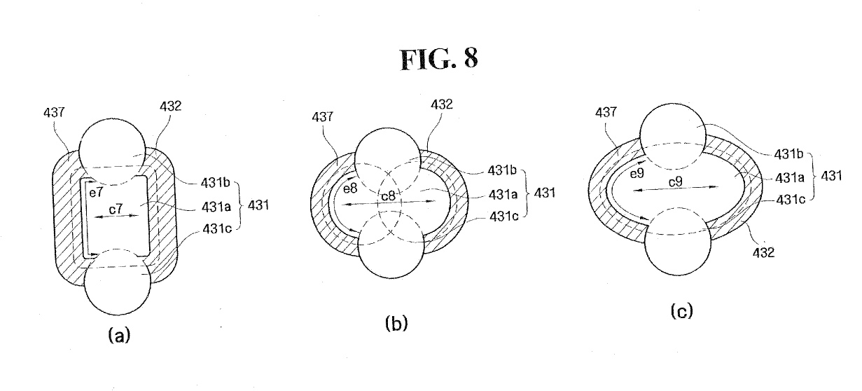

Referring to FIGS. 8(a) through 8(c), a pair of vias 432 and 437 may be formed using a central sub via-hole 431a, which has different shape and size, and a plurality of sub via-holes 431b and 431c. In this case, the widths e7, e8, and e9 of the vias 432 and 437 and the distances c7, c8, and c9 between the pair of vias 432 and 437 may vary depending upon the shape and size of the central sub via-hole 431a.

FIG. 8(a) illustrates the case of using a quadrangular central sub via-hole 431a. Since the vias 432 and 437 are formed on the side wall of the central sub via-hole 431a, the pair of vias 432 and 437 can be formed to be substantially parallel to each other. FIG. 8(b) illustrates the case of using two central sub via-holes 431a, and FIG. 8(c) illustrates the case of using an elliptical central sub via-hole 431a. In the case of forming the vias 432 and 437 according to FIGS. 8(b) and 8(c), the distances c8 and c9 between the pair of vias 432 and 437 can be sufficiently secured. Therefore, by using this principle, the differential impedance of the vias 432 and 437 can be adjusted.

The explanations given above with reference to FIGS. 6 through 8 will be summarized below. In the conventional art, since each via is formed in a separate via-hole, the distance between vias must be greater than the distance between signal patterns. Thus, due to the fact that the differential impedance of a pair of signal patterns and the differential impedance of a pair of vias are different, it is difficult to transmit a signal without distortion. In the present invention, since the pair of vias 232 and 237, 332 and 337, and 432 and 437 are respectively formed in one via hole 231, 331, and 431, the connection regions of a pair of signal patterns are parallel to each other and the differential impedance of the signal patterns may be constant. Also, the distance between the pair of vias 232 and 237, 332 and 337, and 432 and 437 can be adjusted to be substantially similar to the distance between the signal patterns, and the width of the vias can be adjusted. As a consequence, since the differential impedance of the vias 232 and 237, 332 and 337, and 432 and 437 can be adjusted to be the same as that of the signal patterns, it is possible to transmit a signal without distortion.

While sub via-holes 231b and 231c having different positions and sizes, and central via-holes 431a having different shapes and sizes were described with reference to FIGS. 6 through 8, it should be understood that the present invention is not limited to these embodiments. For example, the techniques of FIGS. 6 through 8 may be combined.

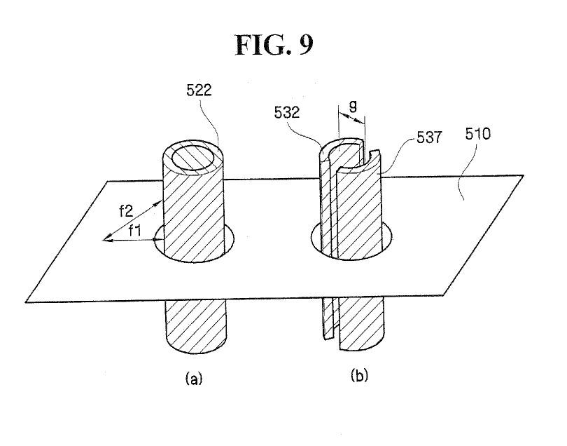

FIG. 9 is a conceptual view explaining characteristics of the circuit board in accordance with an embodiment of the present invention. For the sake of explanatory convenience, only the connection parts are illustrated in the drawing (e.g., the pad parts were omitted.) In contrast to FIGS. 3 through 5, single-ended patterns are exemplified.

FIG. 9(a) illustrates a via 522 used in a conventional circuit board. The via 522 has a cylindrical shape and is formed through a reference layer 510. Here, a ground voltage or a power voltage can be applied to the reference layer 510. The capacitance of the via 522 may be inversely proportional to the distance between the via 522 and the reference layer 510, and the inductance of the via 522 may also be proportional to this distance.

In the conventional circuit board, since the via 522 is formed through the reference layer 510, the distance between the via 522 and the reference layer 510 cannot be kept constant (see f1 and f2), and it is difficult to adjust the impedance of the via 522.

FIG. 9(b) illustrates vias 532 and 537 used in one embodiment of the present invention. The pair of vias 532 and 537 may be formed on the inner wall of a via-hole. A signal is transmitted to the first via 532, and a reference signal of that signal is transmitted to the second via 537. The reference signal can be a ground voltage or a power voltage. Since the distance between the pair of vias 532 and 537 can be kept constant, the capacitance and the inductance of the first via 532 can also be kept constant. Of course, while the capacitance and the inductance of the first via 532 can be influenced by the reference layer 510, because the distance “g” between the first via 532 and the second via 537 is short, the influence of the reference layer 510 can be neglected. Accordingly, the impedance of the first via 532 can be kept constant.

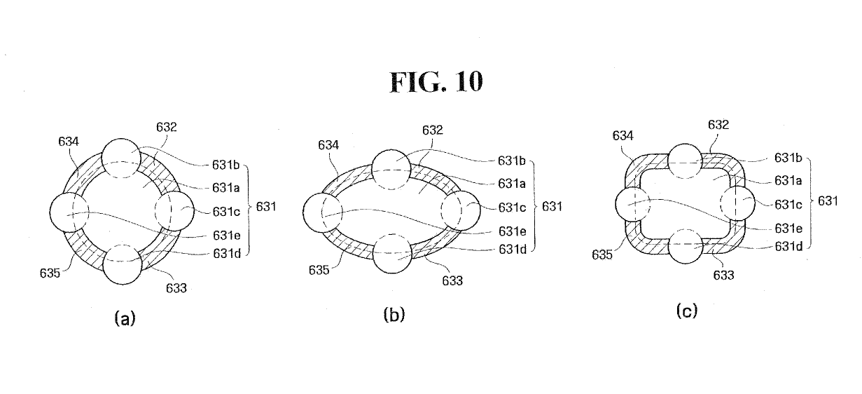

FIG. 10 shows plan views explaining via structures adopted in a circuit board in accordance with another embodiment of the present invention. The elements of this embodiment, which are substantially similar as those appearing in FIGS. 6 through 8, will be designated by the same reference numerals, and detailed explanation thereof has been omitted.

Referring to FIGS. 10(a) through 10(c), four sub via-holes 631b, 631c, 631d, and 631e, which overlap a central sub via-hole 631a, separate four vias 632, 633, 634, and 635 from one another, by which the four vias 632, 633, 634, and 635 are formed in one via-hole 631. In additional embodiments of the present invention, a plurality of vias, for example, six or eight vias, may be formed in one via-hole.

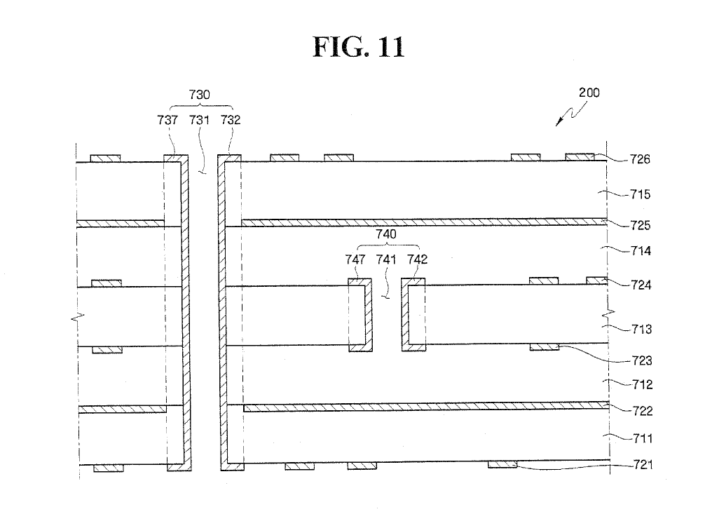

FIG. 11 is a cross-sectional view illustrating a circuit board in accordance with another embodiment of the present invention. While this embodiment exemplifies the case in which six pattern layers are built up, it should be understood that the present invention is not limited to this particular case. The elements of this embodiment that are substantially the same as those appearing in FIGS. 3 through 5 will be designated by the same reference numerals, and detailed explanation thereof will be omitted.

Referring to FIG. 11, the via structures used in a circuit board 200 in accordance with another embodiment of the present invention include a through-type first via structure 730 and a blind-type via structure 740. In other words, the technical concept of the present invention may be applied to all types of via structures 730 and 740.

The circuit board 200 includes signal patterns 721, 723, 724, and 726 which are built up in multiple layers and are respectively insulated by a plurality of dielectric layers 711, 712, 173, 714, and 715. Namely, when viewed from the bottom, the first, third, fourth, and sixth layers of the circuit board 200 comprise the signal patterns 721, 723, 724, and 726, and the second and fifth layers of the circuit board 200 comprise reference layers 722 and 725 to which a ground voltage or a power voltage is applied.

The signal patterns 721, 723, 724, and 726 may comprise differential signal patterns and/or single-ended signal patterns as the occasion demands. For example, when it is necessary to transmit signals such as clock and data signals at high speeds, differential signal patterns may be used, and in the other situations, single-ended signal patterns may be used.

The first and sixth layers of signal patterns 721 and 726 may comprise microstrips, and the third and fourth layers of signal patterns 723 and 724 may comprise strip lines. In detail, the microstrips may indicate the signal patterns formed on the dielectric layers, which are formed on the reference layers 722 and 725 to a predetermined thickness. The microstrips may transmit signals in a quasi-TEM (transverse electromagnetic) mode. The strip lines indicate the signal patterns which are formed between the reference layers 722 and 725 to reduce the crosstalk between the patterns. As the strip lines transmit signals in a full TEM mode, the number of factors contributing to uncertainty may be decreased. Usually, since the pattern of a microstrip is exposed to the outside, it can be easily formed and renders excellent tenability. Further, since a strip line has low impedance and is isolated from an external electric field in order to operate stably, it can be adequately used when high signal integrity is required. However, since the strip line signal patterns 723 and 724 exist between the dielectric layers 712, 713, and 714, they do not permit tunability.

The reference layers 722 and 725 are connected to a ground pin or a power pin to transmit a ground voltage or a power voltage, and serve as references of single-ended signal patterns.

As described above, the multi-layered circuit board 200 includes the through-type first via structure 730 which is formed through the circuit board 200, and the blind-type second via structure 740 which is formed through the third and fourth layers. The first and second via structures 730 and 740 respectively include via-holes 731 and 741 and pairs of vias 732, 737 and 742, 747, which are formed on the inner walls of the via-holes 731 and 741 to connect upper and lower signal patterns (not shown). In this embodiment of the present invention, the via-holes 731 and 741 are defined in such a manner that a plurality of sub via-holes overlap one another. As above, sub via-holes are positioned around a central sub via-hole and are spaced apart by a predetermined interval, and each pair of vias 732, 737 and 742, 747 are formed on the inner wall of the central sub via-hole.

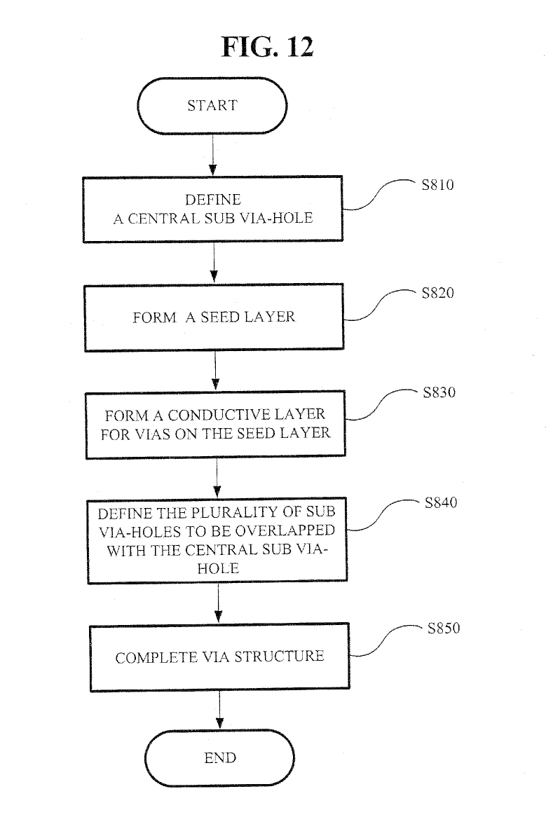

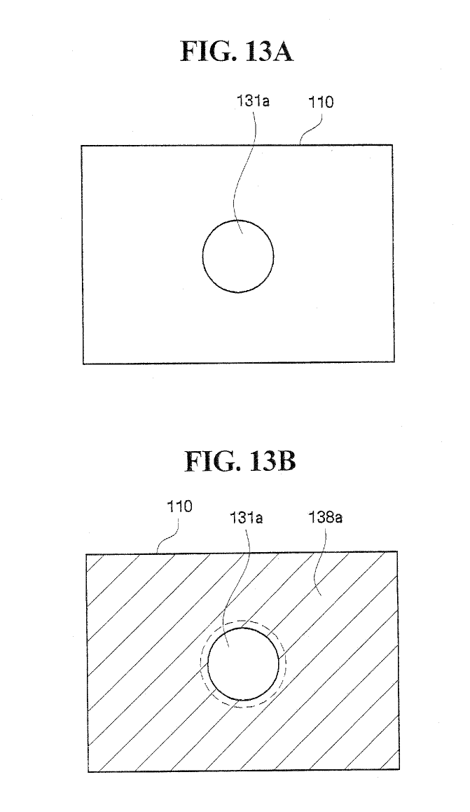

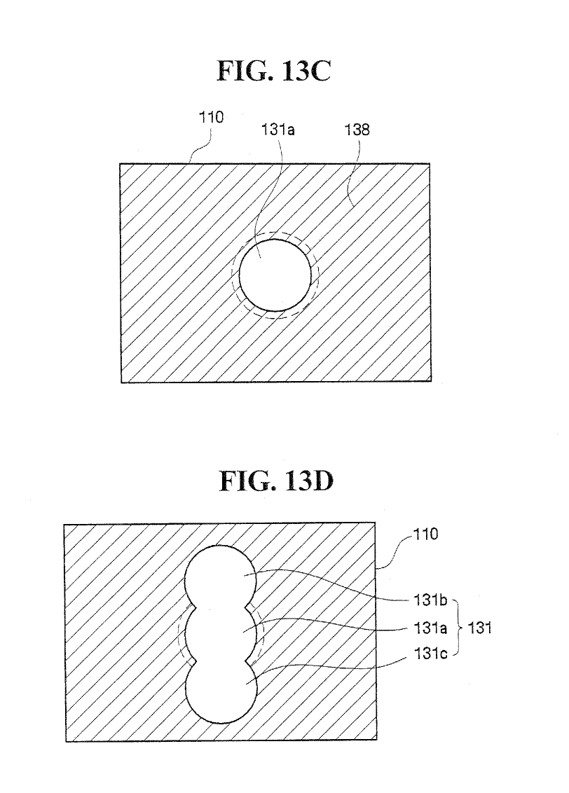

FIG. 12 is a flowchart illustrating a method for manufacturing a circuit board in accordance with another embodiment of the present invention, and FIGS. 13A through 13D are plan views explaining a method for manufacturing a circuit board in accordance with this embodiment of the present invention.

Referring to FIGS. 12 and 13A, the central sub via-hole 131a is defined through the dielectric substrate 110 S810. For example, the central sub via-hole 131a is produced at a predetermined position of the dielectric substrate 110 by mechanical drilling, laser drilling, punching, or other methods.

Referring to FIGS. 12 and 13B, a seed layer 138a is formed on the inner wall of the central sub via-hole 131a S820. In detail, the seed layer 138a is formed on the entire surface of the dielectric substrate 110, which includes the central sub via-hole 131a, using a conductive material such as Cu, Al, Ag, Au, Ni, and so on. The seed layer 138a may be formed by electroless plating.

Referring to FIGS. 12 and 13C, a conductive layer 138 for vias is formed on the seed layer 138a S830. The conductive layer 138 for vias may be mainly formed by electroplating. The conductive layer 138 for vias is formed to have an appropriate thickness in a manner such that the conductive layer 138 can be divided by the sub via-holes defined as described below.

Referring to FIGS. 12 and 13D, a plurality of sub via-holes 131b and 131c are formed to overlap the central sub via-hole 131a S840.

The plurality of sub via-holes 131b and 131c are defined in a manner such that they are positioned at regular intervals around the central sub via-hole 131a. The central sub via-hole 131a and the plurality of sub via-holes 131b and 131c may have the same shape and size. The plurality of sub via-holes 131b and 131c may be defined by mechanical drilling, laser drilling, punching, or other methods. As described above, the plurality of sub via-holes 131b and 131c divide the conductive layer 138 for vias (see FIG. 13C), which are formed on the inner wall of the central sub via-hole 131a.

Referring to FIGS. 12 and 4, by patterning the conductive layer 138 for vias using an etching process, the via structure 130 having the pair of vias 132 and 137, which are electrically isolated from each other, can be completed (S850).

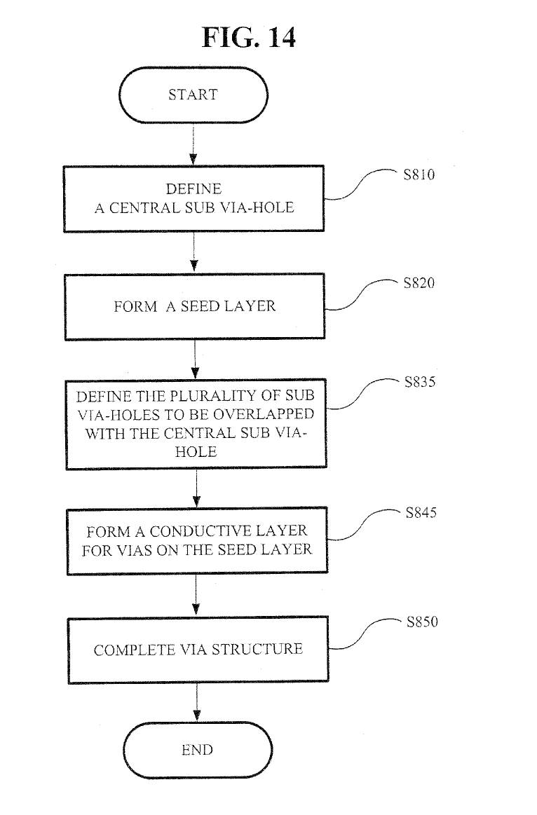

FIG. 14 is a flowchart illustrating a method for manufacturing a circuit board in accordance with still another embodiment of the present invention.

Referring to FIG. 14, in a method for manufacturing a circuit board in accordance with this embodiment of the present invention, before forming the conductive layer 138 for vias by electroplating, the plurality of sub via-holes 131b and 131c are defined to overlap the central sub via-hole 131a S835 and S845. That is to say, since electroplating allows the conductive layer 138 for vias to grow on a zone where the seed layer 138a exists, even when the seed layer 138a is divided using the plurality of sub via-holes 131b and 131c, it is possible to complete the via structure 130 having the pair of vias 132 and 137, which are electrically isolated from each other.

As is apparent from the above descriptions, the circuit board and the method for manufacturing the same according to the present invention provide at least the following advantages.

First, since it is possible to connect a plurality of signal patterns positioned on the upper and lower surfaces of the circuit board using a plurality of vias formed in one via-hole, the area of the circuit board that is occupied by all of the via-holes can be decreased. Therefore, an increased number of signal patterns can be formed in the same area, and the degree of integration of a system can be increased.

Second, because connection regions, where the plurality of signal patterns are connected to the plurality of vias, are parallel to one another, the differential impedance of the signal patterns can be kept constant.

Third, the differential impedance of the vias can be adjusted by regulating the capacitance and the inductance of the vias. Thus, by matching the differential impedance of the signal patterns to that of the vias, the distortion of a signal can be minimized. That is to say, signal integrity can be improved.

Fourth, because a small number of processes are added to the existing processes, the existing manufacturing procedure only needs to be slightly altered.

Although exemplary embodiments of the present invention has been described for illustrative purposes, those skilled in the art will appreciate that various modifications, additions and substitutions are possible, without departing from the scope and spirit of the invention as disclosed in the accompanying claims.

What is claimed is:

1. A circuit board comprising:
a dielectric substrate; and
a first via structure comprising a first via-hole formed through the dielectric substrate, and a plurality of first vias formed on an inner wall of the first via-hole and connecting a plurality of patterns positioned on upper and lower surfaces of the dielectric substrate.

2. The circuit board according to claim 1, wherein the first via-hole includes a plurality of first sub via-holes, where the plurality of first sub via-holes are formed to overlap one another.

3. The circuit board according to claim 2, wherein the plurality of first sub via-holes include a first central sub via-hole and a plurality of first offset sub via-holes that overlap the first central sub via-hole.

4. The circuit board according to claim 3, wherein the first offset sub via-holes are positioned at regular intervals around the first central sub via-hole.

5. The circuit board according to claim 2, wherein the plurality of first sub via-holes have substantially the same shape.

6. The circuit board according to claim 3, wherein the plurality of first vias are formed on an inner wall of the first central sub via-hole.

7. The circuit board according to claim 1, wherein the plurality of upper patterns include a pair of upper patterns, the plurality of lower patterns include a pair of lower patterns, and the plurality of first vias include a pair of first vias.

8. The circuit board according to claim 7, wherein one of the pair of first vias transmits a signal, and the other of the pair of first vias transmits a reference signal.

9. The circuit board according to claim 8, wherein the reference signal is a complementary signal of the signal, a ground voltage signal, or a power voltage signal.

10. The circuit board according to claim 7, wherein the pair of upper patterns and the pair of lower patterns have connection regions where they are connected to the via structure, and where the connection regions of each pair of patterns are parallel to each other.

11. The circuit board according to claim 10, wherein the connection regions of the upper patterns and the lower patterns have a constant differential impedance.

12. The circuit board according to claim 10, wherein the differential impedance of the first vias is substantially the same as that of the upper and lower patterns.

13. The circuit board according to claim 3, wherein the first via-hole is defined in a manner such that two first sub via-holes partially overlap the first central sub via-hole, and the pair of first vias are formed on the inner wall of the first central sub via-hole to electrically connect the pair of upper patterns and the pair of lower patterns, respectively.

14. The circuit board according to claim 13, wherein the pair of upper patterns and the pair of lower patterns have connection regions that are connected to the pair of vias, where the connection regions of each pair of patterns are parallel to each other.

15. The circuit board according to claim 1, wherein the dielectric substrate includes multiple layers of signal patterns which are stacked over one another and are insulated by multiple dielectric layers.

16. The circuit board according to claim 15, further comprising:
a second via structure having a second via-hole formed through the dielectric layer and a plurality of second vias formed on an inner wall of the second via-hole and connect a plurality of signal patterns positioned on upper and lower surfaces of the dielectric layer.

17. A circuit board comprising:
a dielectric substrate formed with a via structure; and
a pair of signal patterns positioned on the dielectric substrate, and connected with the via structure so as to be arranged in one direction, and having parallel connection regions where the signal patterns are connected with the via structure.

18. The circuit board according to claim 17, wherein the connection regions of the pair of signal patterns have a constant differential impedance.

19. The circuit board according to claim 18, wherein one of the pairs of signal patterns transmits a signal, and the other pair of signal patterns transmits a reference signal.

20. The circuit board according to claim 19, wherein the reference signal is a complementary signal of the signal, a ground voltage signal, or a power voltage signal.

21. The circuit board according to claim 17, wherein the via structure includes a via-hole formed through the dielectric substrate, and a pair of vias formed on an inner wall of the via-hole and are respectively connected with the pair of signal patterns.

22. The circuit board according to claim 21, wherein the via-hole includes a central sub via-hole and two offset sub via-holes each partially overlapping the central sub via-hole, and wherein the pair of vias are formed on an inner wall of the central sub via-hole.

23. A method for manufacturing a circuit board, the method comprising:
forming a central sub via-hole through a dielectric substrate;
forming a seed layer on an inner wall of the central sub via-hole;
forming a conductive layer for a via on the seed layer; and
forming at least one offset sub via-hole to overlap the central sub via-hole.

24. The method according to claim 23, wherein the at least one offset sub via-hole is formed before forming the conductive layer for the via.

25. The method according to claim 23, wherein the at least one offset sub via-hole is formed after forming the conductive layer for the via.

26. The method according to claim 23, wherein forming the seed layer is conducted by electroless plating.

27. The method according to claim 23, wherein forming the conductive layer for a via is conducted by electroplating.

28. The method according to claim 23, wherein the central sub via-hole and the at least one offset sub via-hole are formed through a drilling process.

29. A semiconductor device comprising:
a dielectric substrate having a top and bottom surface;
a via hole structure including a first sub via-hole and at least one second sub via-hole;
a first via formed on a first portion of an inner surface of the first sub via-hole and a second via formed on a second portion of the inner surface of the first via hole, the first via formed so as not to contact the second via;
a first upper signal pattern formed on the top surface of the dielectric substrate and electrically connected through the first via to a first lower signal pattern formed on the bottom surface of the dielectric substrate; and
a second upper signal pattern formed on the top surface of the dielectric substrate and electrically connected through the second via to a second lower signal pattern formed on the bottom surface of the dielectric substrate, where the upper first and upper second signal patterns have parallel connection regions in which they are respectively connected to the first and second vias, and where the lower first and lower second signal patterns have parallel connection regions in which they are respectively connected to the first and second vias.

30. The device of claim 29, wherein the first and second vias each include pad portions formed on the top and bottom surfaces of the dielectric layer and a connection portion respectively formed on the first and second inner surface portions of the first sub via-hole.

31. The device of claim 29, wherein first sub via-hole is centrally located between a plurality of offset second sub via-holes, the plurality of offset second sub via-holes overlapping the first sub via-hole.
